(19) United States
(12) Patent Application Publication
(10) Pub. No.: US 2025/0227900 A1
(43) Pub. Date: Jul. 10, 2025

(54) Method and Arrangement for Balancing of DC-Link Voltages in Series Connected Inverters

(71) Applicant: ABB Schweiz AG, Baden (CH)

(72) Inventors: Pavel Kadachigov, Helsinki (FI); Slavko Mocevic, Raleigh, NC (US); Lennart Harnefors, Västerås (SE)

(21) Appl. No.: 18/408,657

(22) Filed: Jan. 10, 2024

(51) Int. Cl. H05K 7/20; H02M 7/00

(52) U.S. Cl. CPC H05K 7/20945; H02M 7/003; H05K 7/20909

(57) ABSTRACT

A field of inverters for controlling electric machines, such as series connected inverters for controlling electric motors and electric generators for industrial applications, and more particularly to a method and arrangement for balancing of DC-link voltages in series connected inverters. The method for balancing of DC-link voltages in series connected inverters which method includes the steps of: receiving in a master controller measured DC-link voltages of two or more series connected inverters; generating in said master controller fan control data and/or fan PWM control signaling for each of two or more cooling fans connected to a DC-link of each of said two or more series connected inverters based on said measured DC-link voltages; and forwarding by said master controller said fan control data and/or said fan PWM control signaling for controlling each of said two or more cooling fans.

### FIELD OF THE INVENTION

The present invention relates to the field of inverters for controlling electric machines, such as series connected inverters for controlling electric motors and electric generators for industrial applications, and more particularly to a method and arrangement for balancing of DC-link voltages in series connected inverters.

### BACKGROUND OF THE INVENTION

Inverter arrangements are widely used for industrial applications, e.g. for providing and controlling electrical power and energy to various public and industrial applications. Inverter arrangements are used in industry for different applications, such as for driving motors within the transportation industry, for driving different devices within the process and manufacturing industry as well as within the energy industry. There are applications commonly used for inverter arrangements within the transportation industry for example in metro and railway traffic applications as well as in ship propulsion unit applications of the marine industry. Within the process and manufacturing industry, inverter arrangements can be used for example in conveyer applications, in mixer applications or even in paper machine applications. Within the energy industry, inverter arrangements can be used for example for driving wind turbines of the wind power industry.

In series connected inverters controlling an electric machines, e.g. a multiphase AC machine, one of the biggest concerns is unacceptably high voltage imbalance of the DC-link capacitors. During operation of the series connected inverters, the DC-link voltage balance between series connected inverters mainly depends on the active power distribution between different inverters, i.e., if the active power is equal voltages are balanced, and if active power is different voltages are unbalanced.

However, during non-driving operation periods when the series connected inverters do not operate and there is no power flow to the electric machine, i.e., during periods of charging, discharging, and stand-by, the system is unstable. This causes problems, as even minor differences in the power consumption of auxiliary circuits or cooling fans between different series connected inverters may lead to abrupt voltage differences.

During non-driving operation periods there exists two types of power loads: non-constant power loads such as balancing resistors with static resistance, and constant power loads, such as auxiliary electronics and cooling fans.

In case when constant power loads consumption and their inherent differences between different series connected inverters overcome power handling capabilities of the internal balancing circuit of the inverter, voltage differences between the DC-link voltages of the series connected inverters will occur. Over time, the voltage over a more loaded capacitor will collapse to zero volts, while the voltage over other capacitor will reach the full system DC-link voltage.

One of the biggest contributor to imbalance of series connected inverters is cooling fans operation point unpredictability due to decentralized control allowing independent operation. Operation points of cooling fans can be different due to difference in temperatures of series connected inverters, which results in different speed references and thus, different power. Simply increasing power handling capabilities of balancing resistors will result in overall reduction of efficiency, which is not desirable, while other solutions such as voltage balancing units and voltage limiting units are energy-inefficient, bulky, and costly.

Prior art solutions for this problem usually deal with the consequence of voltage deviation. In a typical prior art solution voltage balancing units transfer energy between DC-link caps. In another typical prior art solution voltage limiting units discharge the excess energy through resistors.

There is a demand in the market for a solution for balancing of DC-link voltages in series connected inverters, which would introduce a more energy-efficient, compact, cost-effective, and more reliable solution providing a better voltage balance between the series connected inverters.

### SUMMARY

The object of the invention is to introduce a method and an arrangement for balancing of DC-link voltages in series connected inverters, which would introduce a more energy-efficient, compact, cost-effective, and more reliable solution providing a better voltage balance between the series connected inverters. Advantageous embodiments are furthermore presented.

It is brought forward a new method for balancing of DC-link voltages in series connected inverters which method comprises the steps of: receiving in a master controller measured DC-link voltages of two or more series connected inverters; generating in said master controller fan control data and/or fan PWM control signaling for each of two or more cooling fans connected to a DC-link of each of said two or more series connected inverters based on said measured DC-link voltages; and forwarding by said master controller said fan control data and/or said fan PWM control signaling for controlling each of said two or more cooling fans.

In a preferred embodiment of said method, in the step of generating fan PWM control signaling for each of two or more cooling fans is generated in said master controller; and in the step of forwarding said fan PWM control signaling is forwarded to each of said two or more cooling fans by said master controller for controlling each of said two or more cooling fans.

In a preferred embodiment of said method, in the step of generating fan control data for each of two or more cooling fans is generated in said master controller, wherein said fan control data comprises a DC-link reference voltage for each of said two or more series connected inverters; and in the step of forwarding said fan PWM control signaling is forwarded to two or more local controllers arranged to control each of said two or more cooling fans.

In a preferred embodiment, the method comprises the steps of: receiving fan control data from said master controller in a local controller of said two or more local controllers; generating in said local controller fan PWM control signaling for a cooling fan of said two or more cooling fans based on the difference between inverter DC-link voltage and said DC-link reference voltage received from said master controller; and forwarding by said local controller said fan PWM control signaling to said cooling fan for controlling said cooling fan.

In a preferred embodiment of said method, in every microcontroller cycle the ratio of the measured DC-link voltage V_{dc,meas} and a DC-link reference voltage V_{dc,ref} of each of said two or more series connected inverters is computed as a voltage ratio

$$\frac{{V}_{d c , meas}}{{V}_{d c , ref}} ,$$

and wherein based on said computed voltage ratio, the PWM duty cycle of the respective cooling fan is updated.

In a preferred embodiment, said method is activated during a non-driving operation period of the series connected inverters.

In a preferred embodiment, said method is deactivated upon the start of the driving operation period of the series connected inverters.

It is brought forward a new arrangement for balancing of DC-link voltages in series connected inverters comprising two or more series connected inverters arranged to supply power to an electric machine; two or more cooling fans each connected to a DC-link of an inverter unit of said two or more series connected inverters and arranged to cool said inverter unit; two or more local controllers arranged to control each of said two or more cooling fans; and a master controller configured: to receive measured DC-link voltages of two or more series connected inverters, to generate fan control data and/or fan PWM control signaling for each of said two or more cooling fans based on said measured DC-link voltages, and to forward said fan control data and/or said fan PWM control signaling for controlling each of said two or more cooling fans.

In a preferred embodiment, said master controller is configured to generate fan PWM control signaling for each of said two or more cooling fans, and to forward said fan PWM control signaling for controlling each of said two or more cooling fans.

In a preferred embodiment of said arrangement, said master controller is in every microcontroller cycle configured to compute the ratio of the measured DC-link voltage V_{dc,meas} and a DC-link reference voltage V_{dc,ref} of each of said two or more series connected inverters as a voltage ratio

$$\frac{{V}_{d c , meas}}{{V}_{d c , ref}} ,$$

and to update the PWM duty cycle of the respective cooling fan based on said computed voltage ratio.

In a preferred embodiment, said master controller is configured to generate fan control data for each of said two or more cooling fans, and to forward said fan control data for controlling each of said two or more cooling fans, wherein said fan control data comprises a DC-link reference voltage for each of said two or more series connected inverters.

In a preferred embodiment, a local controller of said two or more local controllers controller is configured: to receive fan control data from said master controller, to generate fan PWM control signaling for a cooling fan of said two or more cooling fans based on the difference between inverter DC-link voltage and said DC-link reference voltage received from said master controller, and to forward said fan PWM control signaling to said cooling fan for controlling said cooling fan.

In a preferred embodiment, said master controller is configured to activate said arrangement during a non-driving operation period of the series connected inverters.

In a preferred embodiment, said master controller is configured to deactivate said arrangement upon the start of the driving operation period of the series connected inverters.

In a preferred embodiment, said master controller is configured to control one or more of the series connected inverters.

### BRIEF DESCRIPTION OF THE DRAWINGS

In the following, the present invention will be described in more detail by way of example and with reference to the attached drawings, in which:

FIG. 1 illustrates a flow diagram of an embodiment of a method for balancing of DC-link voltages in series connected inverters according to the present invention.

FIG. 2 illustrates a block diagram of an embodiment of an arrangement for balancing of DC-link voltages in series connected inverters according to the present invention.

FIG. 3 illustrates a flow diagram of another embodiment of a method for balancing of DC-link voltages in series connected inverters according to the present invention.

FIG. 4 illustrates a block diagram of another embodiment of an arrangement for balancing of DC-link voltages in series connected inverters according to the present invention.

FIG. 5 illustrates a flow diagram of a third embodiment of a method in a master controller for balancing of DC-link voltages in series connected inverters according to the present invention.

FIG. 6 illustrates a flow diagram of a third embodiment of a method in a local controller for balancing of DC-link voltages in series connected inverters according to the present invention.

FIG. 7 illustrates an operation of an embodiment of a method for balancing of DC-link voltages in series connected inverters according to the present invention.

The foregoing aspects, features and advantages of the invention will be apparent from the drawings and the detailed description related thereto.

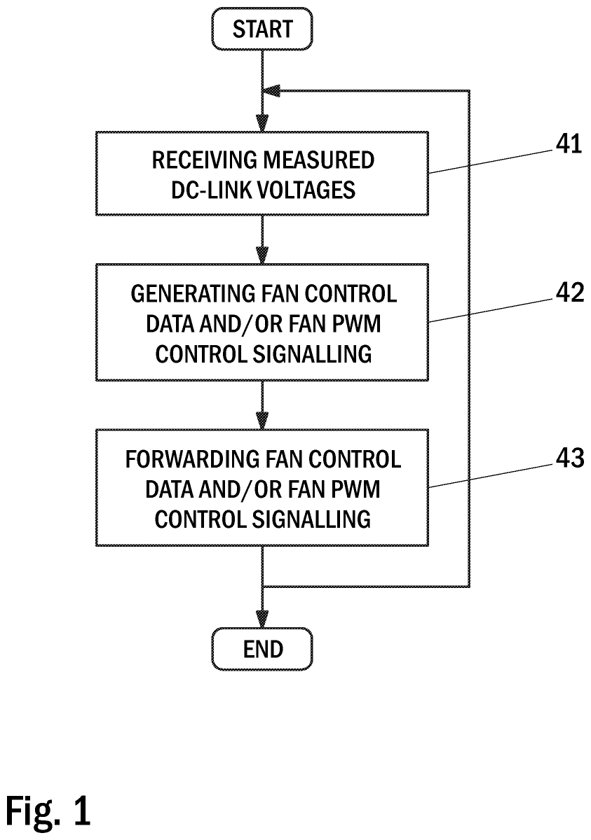

In the following, the invention will be described in greater detail by means of preferred embodiments with reference to the accompanying drawings of FIGS. 1 to 7.

### DETAILED DESCRIPTION

The following embodiments are exemplary. Although the description may refer to “an”, “one”, or “some” embodiment(s) in several locations, this does not necessarily mean that each such reference is to the same embodiment(s), or that the feature only applies to a single embodiment, for example. Single features of different embodiments may also be combined to provide other embodiments. Generally, all terms and expressions used should be interpreted broadly and they are intended to illustrate, not to restrict, the embodiments. The figures only show components necessary for understanding the various embodiments. The number and/or shape of the various elements, and generally their implementation, could vary from the examples shown in the figures. The application of the various embodiments described herein is not limited to any specific system, but it can be used in connection with various applications where the mounting of the electric motor has to be carried out so that the supporting foundation is available only for the non-drive end of the electric motor.

The method of the present invention for balancing of DC-link voltages in series connected inverters comprises the steps of: receiving in a master controller measured DC-link voltages of two or more series connected inverters; generating in said master controller fan control data and/or fan PWM control signaling for each of two or more cooling fans connected to a DC-link of each of said two or more series connected inverters based on said measured DC-link voltages; and forwarding by said master controller said fan control data and/or said fan PWM control signaling for controlling each of said two or more cooling fans.

When referring to a “driving operation period” or “driving operation periods” of series connected inverters, in this application it is meant to comprise the periods when the series connected inverters provide driving operation and there is power flow between said series connected inverters and said electric machine controlled by said series connected inverters.

When referring to a “non-driving operation period” or “non-driving operation periods” of series connected inverters, in this application it is meant to comprise the periods when the series connected inverters do not provide driving operation and there is no power flow between said series connected inverters and said electric machine controlled by said series connected inverters. Examples of said “non-driving operation periods” are charging periods, discharging periods, idle periods, and stand-by periods.

The present invention is utilized for balancing DC-link voltages of series connected inverters. Series connected inverters are commonly used for e.g. for supplying electric power to a multiphase AC machine.

During driving operation periods of the series connected inverters, dc-link voltage balance typically depends on the power distribution between the winding sets of the series-connected inverters, controllable via the main control algorithm.

However, during non-driving operation periods, i.e. during periods when the series connected inverters do not provide driving operation there sometimes appear differences in active power due to different power consumption of cooling fans and/or auxiliary power supplies. This effect over time may lead to substantial differences in DC-link voltages of the DC-link capacitors and cause significant problems.

The present invention provides an energy-efficient, compact, cost-effective, and reliable solution to this problem. The solution according to the present invention is used during non-driving operation periods, i.e. during periods when the series connected inverters do not operate and there is no power flow to the multiphase AC machine.

FIG. 1 illustrates a flow diagram of an embodiment of a method for balancing of DC-link voltages in series connected inverters according to the present invention. The method according to the present embodiment is activated during a non-driving operation period of the series connected inverters. In the method according to the present embodiment, measured DC-link voltages of two or more series connected inverters are received 41 in a master controller.

As the next step in said master controller fan control data and/or fan PWM control signaling is generated 42 for each of two or more cooling fans connected to a DC-link of each of said two or more series connected inverters based on said measured DC-link voltages.

Thereafter, in said master controller said fan control data and/or said fan PWM control signaling is forwarded 43 for controlling each of said two or more cooling fans. In the method according to the present embodiment, the steps of receiving measured DC-link voltages 41, generating fan control data and/or fan PWM control signaling 42 and forwarding fan control data and/or fan PWM control signaling 43 are repeated several times in a continuous loop, as deemed necessary. Upon entering the driving operation period and the series connected inverters start switching, the method according to the present embodiment is deactivated and the fan control returns to standard temperature referenced control executed by the local controllers. In an embodiment of the present invention said master controller is configured to control one or more of the series connected inverters.

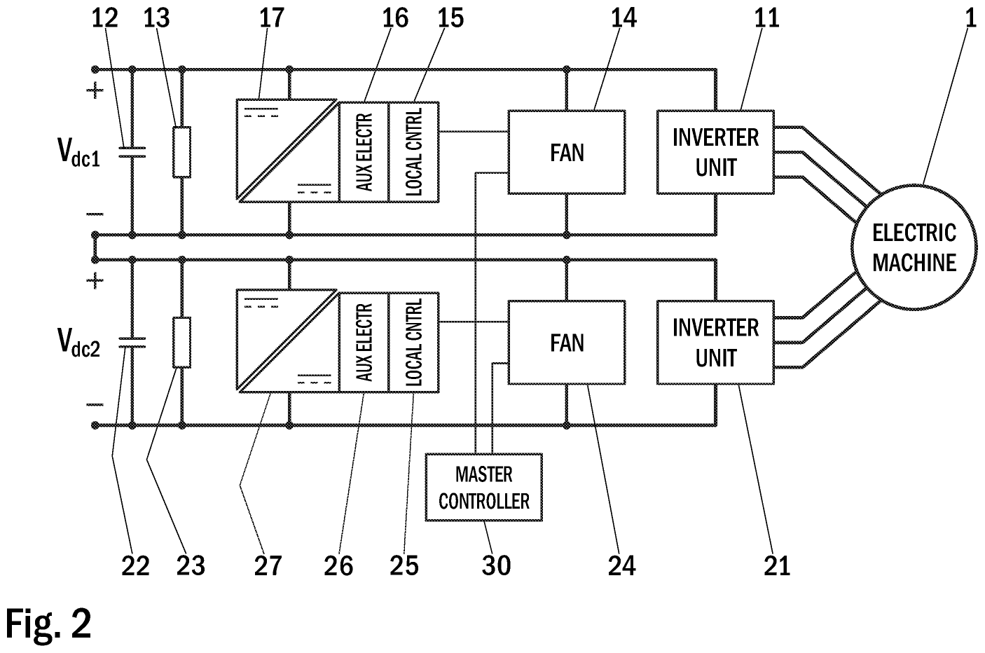

FIG. 2 illustrates a block diagram of an embodiment of an arrangement for balancing of DC-link voltages in series connected inverters according to the present invention. The arrangement for balancing of DC-link voltages in series connected inverters according to the present embodiment comprises a first inverter unit 11 and a second inverter unit 21, which inverter units 11, 21 are series connected inverters 11, 21 connected in series and arranged to supply power to an electric machine 1. Said electric machine 1 may e.g. be a multiphase AC machine.

In the presented embodiment of FIG. 2 a first dc-link capacitor 12 is connected to a DC-link of said first inverter unit 11 and respectively a second dc-link capacitor 22 is connected to a DC-link of said second inverter unit 21. Also in the presented embodiment a first resistance 13 is connected to said first inverter unit 11 and respectively a second resistance 23 is connected to said second inverter unit 21.

The arrangement according to the present embodiment comprises a first cooling fan 14 connected to a DC-link of said first inverter unit 11 and arranged to cool said first inverter unit 11 and respectively a second cooling fan 24 connected to a DC-link of said second inverter unit 21 and arranged to cool said second inverter unit 21.

The arrangement according to the present embodiment comprises a first isolated DC/DC converter 17 connected to a DC-link of said first inverter unit 11 and respectively a second isolated DC/DC converter 27 connected to a DC-link of said second inverter unit 21.

The arrangement according to the present embodiment also comprises a first auxiliary electronics unit 16 connected via said first isolated DC/DC converter 17 to a DC-link of said first inverter unit 11 and a second auxiliary electronics unit 26 connected via said second isolated DC/DC converter 27 to a DC-link of said second inverter unit 21.

The arrangement according to the present embodiment also comprises a first local controller 15 connected via said first isolated DC/DC converter 17 to a DC-link of said first inverter unit 11 and arranged to control said first cooling fan 14 and a second local controller 25 connected via said second isolated DC/DC converter 27 to a DC-link of said second inverter unit 21 and arranged to control said second cooling fan 24.

In the arrangement according to the present another embodiment the first local controller 15 controls said first cooling fan 14 during the operation of said series connected inverters 11, 21 and said electric machine 1. Respectively, the second local controller 25 controls said second cooling fan 24 during the operation of said series connected inverters 11, 21 and said electric machine 1.

The arrangement according to the present embodiment also comprises a master controller 30 connected to said first cooling fan 14 and said second cooling fan 24.

In the arrangement according to the present embodiment during a non-driving operation period of said series connected inverters 11, 21 said master controller 30 is arranged to receive measured DC-link voltages of said series connected inverters 11, 21.

Furthermore, in the arrangement according to the present embodiment said master controller 30 is arranged to generate fan PWM control signaling based on said measured DC-link voltages. Furthermore, in the arrangement according to the present embodiment said master controller 30 is arranged and to forward said fan PWM control signaling to said first cooling fan 14 and said second cooling fan 24 for controlling each of said first cooling fan 14 and said second cooling fan 24.

In the arrangement according to the present embodiment, the master controller 30 collects DC-link voltages of the series connected inverters 11, 21, generates the fan PWM control signals based on said measured DC-link voltages, and sends said fan PWM control signals to individual inverter cooling fans 14, 24. In an embodiment of the present invention said master controller is configured to control one or more of the series connected inverters.

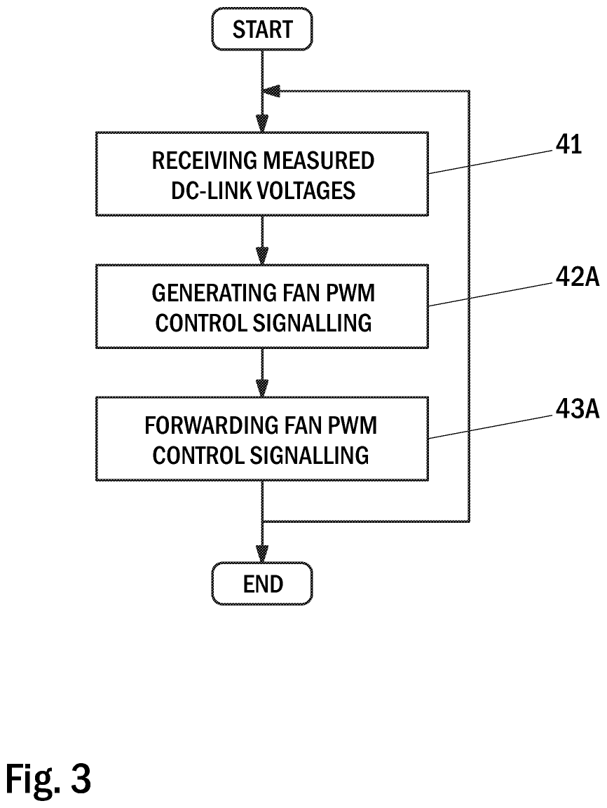

FIG. 3 illustrates a flow diagram of another embodiment of a method for balancing of DC-link voltages in series connected inverters according to the present invention. The method according to the present another embodiment is activated during a non-driving operation period of the series connected inverters. In the method according to the present another embodiment, measured DC-link voltages of two or more series connected inverters are received 41 in a master controller.

As the next step in said master controller fan PWM control signaling is generated 42A for each of two or more cooling fans connected to a DC-link of each of said two or more series connected inverters based on said measured DC-link voltages.

Thereafter, in said master controller said fan PWM control signaling is forwarded 43A to each of said two or more cooling fans for controlling each of said two or more cooling fans. In the method according to the present another embodiment, the steps of receiving measured DC-link voltages 41, generating fan PWM control signaling 42A and forwarding fan PWM control signaling 43A are repeated several times in a continuous loop, as deemed necessary.

In the method according to the present another embodiment, in every microcontroller cycle, DC-link voltages measurements of each of the two or more series connected inverters are sampled, and the ratio of the measured DC-link voltage V_{dc,meas} and a DC-link reference voltage V_{dc,ref} is computed as a voltage ratio

$$\frac{{V}_{d c , meas}}{{V}_{d c , ref}} .$$

Based on this voltage ratio, the respective cooling fan PWM duty cycle, i.e. speed reference, is updated. In the method according to the present another embodiment, if voltages tend to diverge, speeds of cooling fans change proportionally to the rate divergence. This means that for inverters with

$$\frac{{V}_{d c , meas}}{{V}_{d c , ref}} \geq 1 ,$$

speed is increased, while for inverters with

$$\frac{{V}_{d c , meas}}{{V}_{d c , ref}} < 1$$

speed is decreased.

In the method according to the present another embodiment, the master controller collects and receives 41 DC-link voltages of each of the two or more series connected inverters, generates 42A the fan PWM control signals based on said measured DC-link voltages, and sends 43A said fan PWM control signals to each of said two or more individual inverter cooling fans. Upon entering the driving operation period and the series connected inverters start switching, the method according to the present embodiment is deactivated and the fan control returns to standard temperature referenced control executed by the local controllers. In an embodiment of the present invention said master controller is configured to control one or more of the series connected inverters.

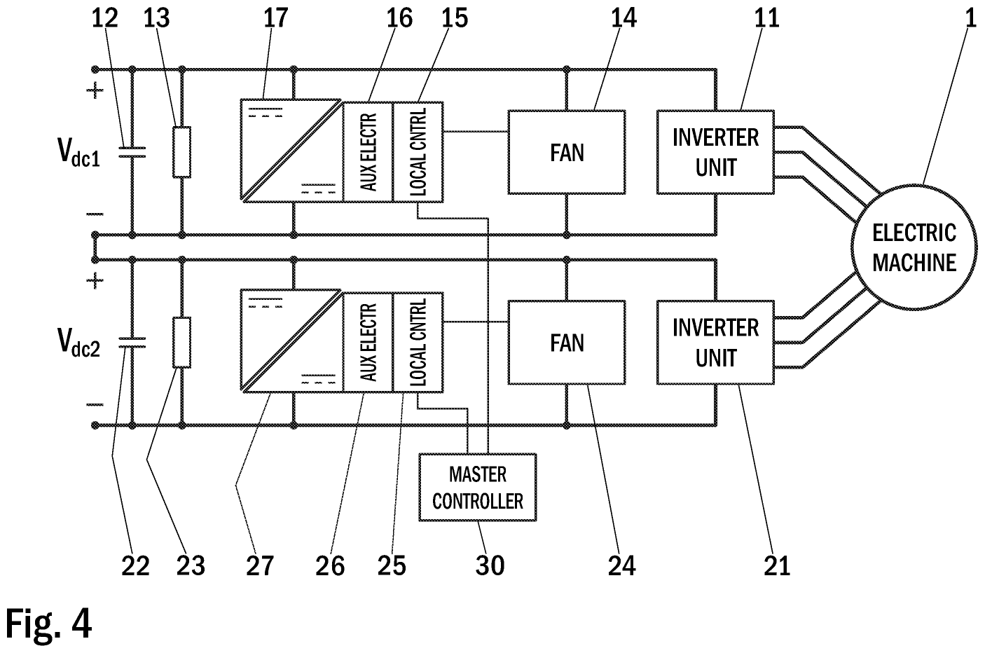

FIG. 4 illustrates a block diagram of another embodiment of an arrangement for balancing of DC-link voltages in series connected inverters according to the present invention. The arrangement for balancing of DC-link voltages in series connected inverters according to the present another embodiment comprises a first inverter unit 11 and a second inverter unit 21, which inverter units 11, 21 are series connected inverters 11, 21 connected in series and arranged to supply power to an electric machine 1. Said electric machine 1 may e.g. be a multiphase AC machine. In the presented another embodiment of FIG. 4 a first dc-link capacitor 12 is connected to a DC-link of said first inverter unit 11 and respectively a second dc-link capacitor 22 is connected to a DC-link of said second inverter unit 21. Also in the presented another embodiment a first resistance 13 is connected to said first inverter unit 11 and respectively a second resistance 23 is connected to said second inverter unit 21.

The arrangement according to the present another embodiment comprises a first cooling fan 14 connected to a DC-link of said first inverter unit 11 and arranged to cool said first inverter unit 11 and respectively a second cooling fan 24 connected to a DC-link of said second inverter unit 21 and arranged to cool said second inverter unit 21.

The arrangement according to the present another embodiment comprises a first isolated DC/DC converter 17 connected to a DC-link of said first inverter unit 11 and respectively a second isolated DC/DC converter 27 connected to a DC-link of said second inverter unit 21.

The arrangement according to the present another embodiment also comprises a first auxiliary electronics unit 16 connected via said first isolated DC/DC converter 17 to a DC-link of said first inverter unit 11 and a second auxiliary electronics unit 26 connected via said second isolated DC/DC converter 27 to a DC-link of said second inverter unit 21.

The arrangement according to the present another embodiment also comprises a first local controller 15 connected via said first isolated DC/DC converter 17 to a DC-link of said first inverter unit 11 and arranged to control said first cooling fan 14 and a second local controller 25 connected via said second isolated DC/DC converter 27 to a DC-link of said second inverter unit 21 and arranged to control said second cooling fan 24.

In the arrangement according to the present another embodiment the first local controller 15 controls said first cooling fan 14 during the operation of said series connected inverters 11, 21 and said electric machine 1. Respectively, the second local controller 25 controls said second cooling fan 24 during the operation of said series connected inverters 11, 21 and said electric machine 1.

The arrangement according to the present another embodiment also comprises a master controller 30 connected to said first local controller 15 and said second local controller 25. In the arrangement according to the present another embodiment during a non-driving operation period of said series connected inverters 11, 21 said master controller 30 is arranged to receive measured DC-link voltages of said series connected inverters 11, 21.

Furthermore, in the arrangement according to the present another embodiment said master controller 30 is arranged to generate fan control data for controlling each of said first cooling fan 14 and said second cooling fan 24 based on said measured DC-link voltages. In the arrangement according to the present another embodiment said fan control data comprises a DC-link reference voltage for each of said series connected inverters 11, 21.

Furthermore, in the arrangement according to the present another embodiment said master controller 30 is arranged and to forward said fan control data to said first local controller 15 and said second local controller 25 for controlling each of said first cooling fan 14 and said second cooling fan 24.

In the arrangement according to the present another embodiment said first local controller 15 and said second local controller 25 each generate fan PWM control signaling for controlling each of said first cooling fan 14 and said second cooling fan 24 based on the difference between inverter DC-link voltage and said DC-link reference voltage received from master controller 30.

Furthermore, in the arrangement according to the present another embodiment said first local controller 15 and said second local controller 25 are arranged and to forward said fan PWM control signaling to said first cooling fan 14 and said second cooling fan 24 for controlling each of said first cooling fan 14 and said second cooling fan 24.

In the arrangement according to the present another embodiment, the fan PWM control signals are generated in said first local controller 15 and said second local controller 25 based on the difference between the inverter DC-link voltage and the DC-link reference voltage received from master controller 30. In an embodiment of the present invention said master controller is configured to control one or more of the series connected inverters.

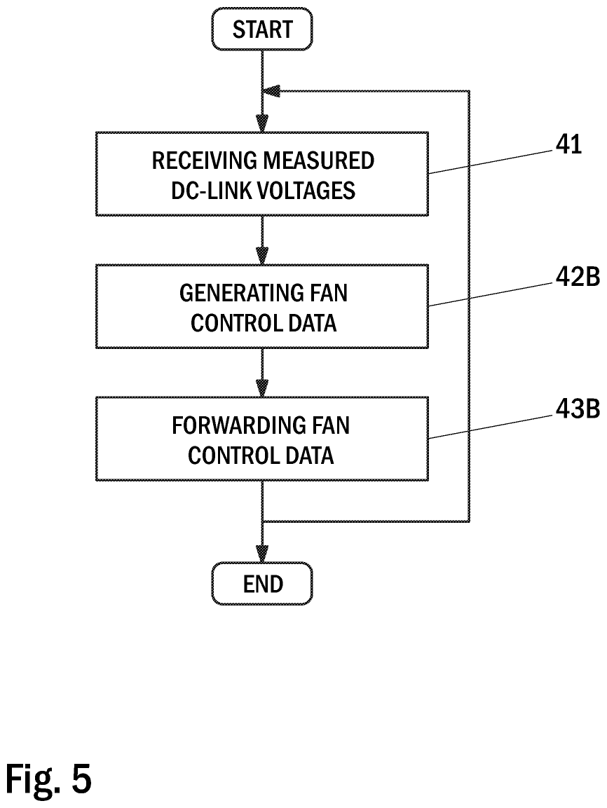

FIG. 5 illustrates a flow diagram of a third embodiment of a method in a master controller for balancing of DC-link voltages in series connected inverters according to the present invention. The method according to the present third embodiment is activated during a non-driving operation period of the series connected inverters. In the method according to the present third embodiment, measured DC-link voltages of two or more series connected inverters are received 41 in a master controller.

As the next step in said master controller fan control data is generated 42B for each of two or more cooling fans connected to a DC-link of each of said two or more series connected inverters based on said measured DC-link voltages. In the arrangement according to the present third embodiment said fan control data comprises a DC-link reference voltage for each of said two or more series connected inverters.

Thereafter, in said master controller said fan control data is forwarded 43B to two or more local controllers arranged to control each of said two or more cooling fans.

After said fan control data is received in said two or more local controllers, fan PWM control signaling is generated for controlling each of said two or more cooling fans based on the difference between inverter DC-link voltage and said DC-link reference voltage received from said master controller. In the method according to the present third embodiment, the steps of receiving measured DC-link voltages 41, generating fan control data 42B and forwarding fan control data 43B are repeated in said master controller several times in a continuous loop, as deemed necessary. Upon entering the driving operation period and the series connected inverters start switching, the method according to the present embodiment is deactivated the fan control returns to standard temperature referenced control executed by the local controllers.

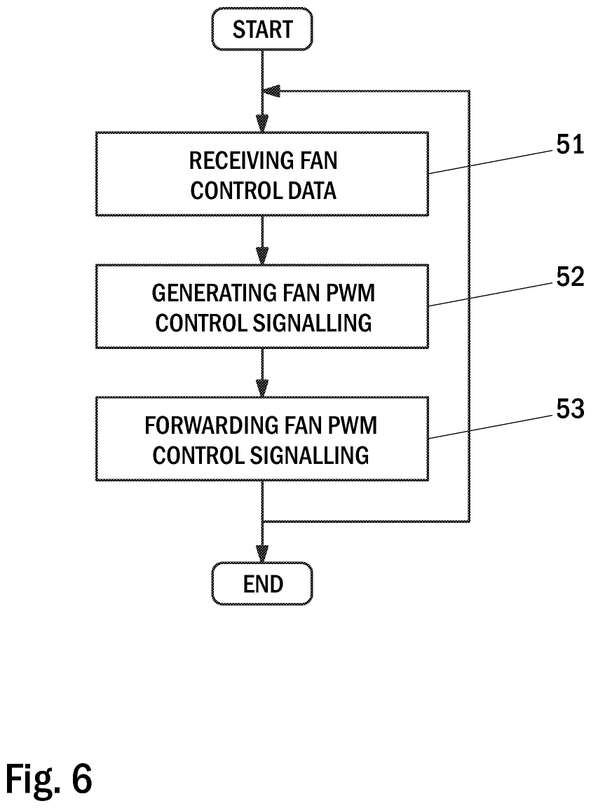

FIG. 6 illustrates a flow diagram of a third embodiment of a method in a local controller for balancing of DC-link voltages in series connected inverters according to the present invention. The method according to the present third embodiment is activated during a non-driving operation period of the series connected inverters. In the method according to the present third embodiment, fan control data from a master controller is received 51 in a local controller of two or more local controllers arranged to control each of said two or more cooling fans. In the arrangement according to the present third embodiment said fan control data comprises a DC-link reference voltage for a series connected inverter of two or more series connected inverters.

As the next step in said local controller fan PWM control signaling is generated 52 for controlling a cooling fan of said two or more cooling fans based on the difference between inverter DC-link voltage and said DC-link reference voltage received from said master controller.

After generating 52 said fan PWM control signaling in said local controller, said fan PWM control signaling is forwarded 53 to a cooling fan of said two or more cooling fans for controlling said cooling fan. In the method according to the present third embodiment, the steps of receiving fan control data 51, generating fan PWM control signaling 52 and forwarding fan PWM control signaling 53 are repeated in said local controller several times in a continuous loop, as deemed necessary.

In the method according to the present embodiment, in every microcontroller cycle, DC-link voltages measurements of each of the two or more series connected inverters are sampled, and the ratio of the measured DC-link voltage V_{dc,meas} and a DC-link reference voltage V_{dc,ref} is computed as a voltage ratio

$$\frac{{V}_{d c , meas}}{{V}_{d c , ref}} .$$

Based on this voltage ratio, the respective cooling fan PWM duty cycle, i.e. speed reference, is updated. In the method according to the present embodiment, if voltages tend to diverge, speeds of cooling fans change proportionally to the rate divergence. This means that for inverters with

$$\frac{{V}_{d c , meas}}{{V}_{d c , ref}} \geq 1 ,$$

speed is increased, while for inverters with

$$\frac{{V}_{d c , meas}}{{V}_{d c , ref}} < 1$$

speed is decreased.

In the method according to the present embodiment, the fan PWM control signals are generated in each local controller of said two or more local controllers based on the difference between the inverter DC-link voltage and the DC-link reference voltage received from master controller 30. Upon entering the driving operation period and the series connected inverters start switching, the method according to the present embodiment is deactivated the fan control returns to standard temperature referenced control executed by the local controllers.

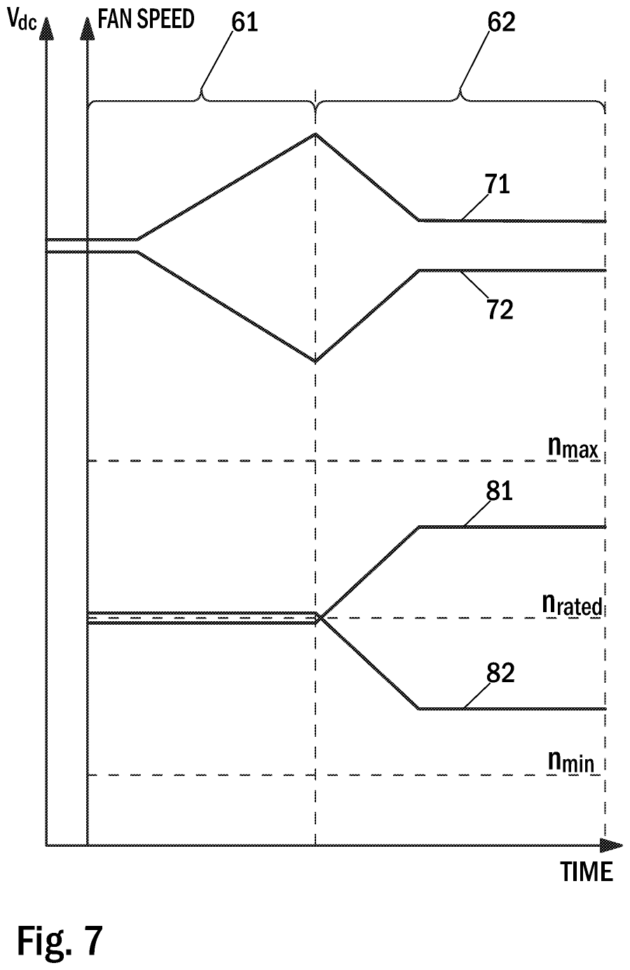

FIG. 7 illustrates an operation of an embodiment of a method for balancing of DC-link voltages in series connected inverters according to the present invention. In FIG. 7 time is presented in horizontal axis and both inverter DC-link voltage and cooling fan speed are presented in vertical axis. In FIG. 7 time in the horizontal time axis is divided to two portions 61, 62. The first portion 61 shows the time when the method for balancing of DC-link voltages in series connected inverters according to the present invention is not activated. Respectively, the second portion 62 shows the time when the method for balancing of DC-link voltages in series connected inverters according to the present invention is in active operation.

During the first portion 61 as the method according to the present invention is not activated the first DC-link voltage 71 of a first inverter increases and the second DC-link voltage 72 of a second inverter decreases. So the first DC-link voltage 71 and the second DC-link voltage 72 diverge. During the first portion 61 both the first fan speed 81 of a first cooling fan cooling said first inverter and the second fan speed 82 of a second cooling fan cooling said second inverter remain close to the cooling fan rated nominal speed n_{rated}.

After the first portion 61, as the method according to the present invention is activated to be in active operation the second portion 62 is started. During the second portion 62, the first fan speed 81 of the first cooling fan rises and the second fan speed 82 of the second cooling fan decreases. In FIG. 7 the cooling fan minimum speed nₘᵢₙ is indicated with a dashed line. Likewise in FIG. 7, the cooling fan maximum speed nₘₐₓ is indicated with a dashed line. In the arrangement according to the present embodiment, the allowable area of balancing is the area of duty cycle change, i.e. from the cooling fan minimum speed nₘᵢₙ to the cooling fan maximum speed nₘₐₓ. Therefore, the balancing capability of method according to the present invention is limited by the cooling fan top speed and the consumed power.

In the arrangement according to the present embodiment during the second portion 62, the increased first fan speed 81 of the first cooling fan increases the power consumption, this leading to decrease of the first DC-link voltage 71 of the first inverter. Respectively, the decreased second fan speed 82 of the second cooling fan decreases the power consumption, this leading to increase of the second DC-link voltage 72 of the second inverter. So in accordance with the present invention this leads to a better voltage balance of DC-link voltages between series connected inverters.

With the help of the present invention there is provided an advanced and effective solution for balancing of DC-link voltages in series connected inverters. The present invention prevents voltage deviation by controlling the speed of the cooling fans of the series connected inverters, thus altering their power consumption. Compared to the prior art solutions, the present invention provides a more energy-efficient, compact, cost-effective, and more reliable solution.

The present invention prevents voltage deviation of the series connected inverters during non-driving operation periods, such as during charging, idle, and discharging operation periods. The present invention controls the speeds of the cooling fans of individual inverters allowing alteration of their power consumption leading towards a better voltage balance between the series connected inverters.

It is to be understood that the above description and the accompanying Figures are only intended to teach the best way known to the inventors to make and use the invention. It will be apparent to a person skilled in the art that the inventive concept can be implemented in various ways. The above-described embodiments of the invention may thus be modified or varied, without departing from the invention, as appreciated by those skilled in the art in light of the above teachings. It is therefore to be understood that the invention and its embodiments are not limited to the examples described above but may vary within the scope of the claims and their equivalents.

1. A method for balancing of DC-link voltages in series connected inverters which method includes the steps of:
receiving in a master controller measured DC-link voltages of two or more series connected inverters;
generating in said master controller fan control data and/or fan PWM control signaling for each of two or more cooling fans connected to a DC-link of each of said two or more series connected inverters based on said measured DC-link voltages; and
forwarding by said master controller said fan control data and/or said fan PWM control signaling for controlling each of said two or more cooling fans.

2. The method of claim 1, wherein:
in the step of generating fan PWM control signaling for each of two or more cooling fans is generated in said master controller; and
in the step of forwarding said fan PWM control signaling is forwarded to each of said two or more cooling fans by said master controller for controlling each of said two or more cooling fans.

3. The method of claim 1, wherein:
in the step of generating fan control data for each of two or more cooling fans is generated in said master controller, wherein said fan control data comprises a DC-link reference voltage for each of said two or more series connected inverters; and
in the step of forwarding said fan PWM control signaling is forwarded to two or more local controllers arranged to control each of said two or more cooling fans.

4. The method of claim 3, wherein the method comprises the steps of:
receiving fan control data from said master controller in a local controller of said two or more local controllers;
generating in said local controller fan PWM control signaling for a cooling fan of said two or more cooling fans based on the difference between inverter DC-link voltage and said DC-link reference voltage received from said master controller; and
forwarding by said local controller said fan PWM control signaling to said cooling fan for controlling said cooling fan.

5. The method of claim 1, wherein in every microcontroller cycle the ratio of the measured DC-link voltage V_{dc,meas} and a DC-link reference voltage V_{dc,ref} of each of said two or more series connected inverters is computed as a voltage ratio
$$\frac{{V}_{d c , meas}}{{V}_{d c , ref}} ,$$
and wherein based on said computed voltage ratio, the PWM duty cycle of the respective cooling fan is updated.

6. The method of claim 1, wherein said method is activated during a non-driving operation period of the series connected inverters.

7. The method of claim 1, wherein said method is deactivated upon the start of the driving operation period of the series connected inverters.

8. An arrangement for balancing of DC-link voltages in series connected inverters comprising:
two or more series connected inverters arranged to supply power to an electric machine;
two or more cooling fans each connected to a DC-link of an inverter unit of said two or more series connected inverters and arranged to cool said inverter unit;
two or more local controllers arranged to control each of said two or more cooling fans; and
a master controller configured: to receive measured DC-link voltages of two or more series connected inverters, to generate fan control data and/or fan PWM control signaling for each of said two or more cooling fans based on said measured DC-link voltages, and to forward said fan control data and/or said fan PWM control signaling for controlling each of said two or more cooling fans.

9. The arrangement of claim 8, wherein said master controller is configured to generate fan PWM control signaling for each of said two or more cooling fans, and to forward said fan PWM control signaling for controlling each of said two or more cooling fans.

10. The arrangement of claim 8, wherein said master controller is in every microcontroller cycle configured to compute the ratio of the measured DC-link voltage V_{dc,meas} and a DC-link reference voltage V_{dc,ref} of each of said two or more series connected inverters as a voltage ratio
$$\frac{{V}_{d c , meas}}{{V}_{d c , ref}} ,$$
and to update the PWM duty cycle of the respective cooling fan based on said computed voltage ratio.

11. The arrangement of claim 8, wherein said master controller is configured to generate fan control data for each of said two or more cooling fans, and to forward said fan control data for controlling each of said two or more cooling fans, wherein said fan control data comprises a DC-link reference voltage for each of said two or more series connected inverters.

12. The arrangement of claim 11, wherein a local controller of said two or more local controllers controller is configured: to receive fan control data from said master controller, to generate fan PWM control signaling for a cooling fan of said two or more cooling fans based on the difference between inverter DC-link voltage and said DC-link reference voltage received from said master controller, and to forward said fan PWM control signaling to said cooling fan for controlling said cooling fan.

13. The arrangement of claim 8, wherein said master controller is configured to activate said arrangement during a non-driving operation period of the series connected inverters.

14. The arrangement of claim 8, wherein said master controller is configured to deactivate said arrangement upon the start of the driving operation period of the series connected inverters.

15. The arrangement of claim 8, wherein said master controller is configured to control one or more of the series connected inverters.
